(19) United States
(12) Patent Application Publication
(10) Pub. No.: US 2011/0215874 A1
(43) Pub. Date: Sep. 8, 2011

(54) NON-LINEAR OSCILLATOR

(76) Inventor: Yeong-Jeu Sun, Kaohsiung (TW)

(21) Appl. No.: 12/902,461

(22) Filed: Oct. 12, 2010

(30) Foreign Application Priority Data
Mar. 3, 2010 (TW) 099106138

(51) Int. Cl. H03L 7/00

(52) U.S. Cl. 331/34

(57) ABSTRACT

A non-linear oscillator for generating a first sinusoidal signal and a second sinusoidal signal includes a comparing device, a computing device, an integrator device, and a feedback device. The comparing device is operable to compare a reference signal with a feedback signal and output a comparison signal based on result of comparison made thereby. The computing device is operable to output first and second combined signals according to a predetermined frequency value, the comparison signal, the feedback signal and the first and second sinusoidal signals. The integrator device is operable to perform integration upon the first and second combined signals to output the first and second sinusoidal signals. The feedback device is operable to output the feedback signal to the comparing device and the computing device according to a first predetermined amplitude value and the first and second sinusoidal signals from the integrator device.

### BACKGROUND OF THE INVENTION

1. Field of the Invention

The present invention relates to an oscillator, more particularly to a non-linear oscillator.

2. Description of the Related Art

A function generator is generally used for generating a signal in an experiment. However, the function generator is expensive and is not an economical choice.

Since a signal used for an experiment is mostly periodic, a linear oscillator is usually used for generating the periodic signal. Parameters of the linear oscillator have to satisfy a condition that a pair of conjugate poles are both at the imaginary axis, such that the linear oscillator can oscillate as a sine wave. However, in practice, the parameters of the linear oscillator are affected unavoidably by temperature, pressure, humidity, and other uncertain factors. Accordingly, a signal generated by the linear oscillator upon oscillation is not as expected and an amplitude value thereof may even diverge or converge to 0.

### SUMMARY OF THE INVENTION

Therefore, an object of the present invention is to provide a non-linear oscillator capable of generating a sinusoidal signal substantially unaffected by environmental factors.

Accordingly, a non-linear oscillator of the present invention is configured for generating a first sinusoidal signal and a second sinusoidal signal. The non-linear oscillator is adapted to receive a reference signal and comprises a comparing device, a computing device, an integrator device, and a feedback device.

The comparing device is configured for receiving the reference signal, and is operable to compare the reference signal with a feedback signal and output a comparison signal based on result of comparison made thereby. The computing device is coupled to the comparing device, and is operable to output first and second combined signals according to a predetermined frequency value, the comparison signal, the feedback signal and the first and second sinusoidal signals. The integrator device is coupled to the computing device, and is operable to perform integration upon the first and second combined signals to output the first and second sinusoidal signals. The feedback device is coupled to the comparing device, the computing device and the integrator device, and is operable to output the feedback signal to the comparing device and the computing device according to a predetermined amplitude value and the first and second sinusoidal signals from the integrator device.

### BRIEF DESCRIPTION OF THE DRAWINGS

Other features and advantages of the present invention will become apparent in the following detailed description of the preferred embodiments with reference to the accompanying drawings, of which:

FIG. 1 is a block diagram illustrating a first preferred embodiment of a non-linear oscillator of the present invention;

FIG. 2 is a block diagram illustrating components of the non-linear oscillator;

FIG. 3 is a schematic circuit diagram of the non-linear oscillator of the first preferred embodiment;

FIG. 4 is a plot of simulation results showing waveforms of sinusoidal signals generated using the non-linear oscillator of the first preferred embodiment;

FIG. 5 is a plot of simulation results showing waveforms of sinusoidal signals generated using the non-linear oscillator with a different set of parameters; and

FIG. 6 is a schematic circuit diagram of a second preferred embodiment of a non-linear oscillator according to the present invention.

### DETAILED DESCRIPTION OF THE PREFERRED EMBODIMENTS

Before the present invention is described in greater detail, it should be noted that like elements are denoted by the same reference numerals throughout the disclosure.

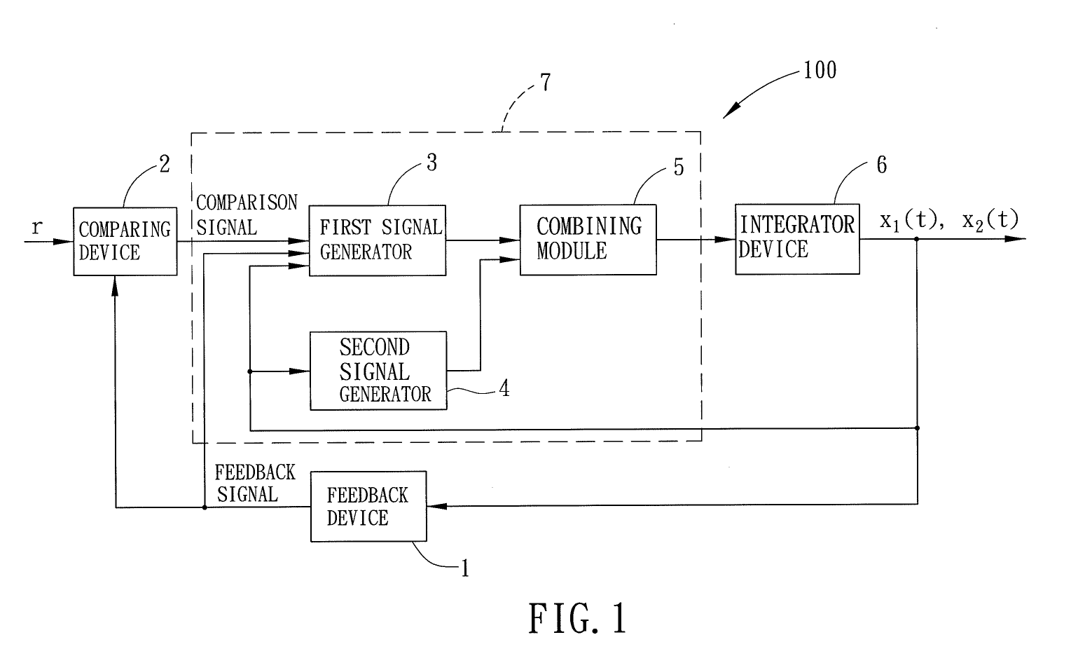

FIG. 1 illustrates a first preferred embodiment of a non-linear oscillator 100 of the present invention. After first and second predetermined amplitude values a, b and a predetermined frequency value ω have been set, the non-linear oscillator 100 is operable to generate a pair of sinusoidal signals both having a frequency ω after receiving a reference signal r. In particular, the sinusoidal signals include a first sinusoidal signal x₁(t) approximating a cos(ωt+θ₀) and a second sinusoidal signal x₂(t) approximating b sin(ωt+θ₀, where a, b and ω are greater than 0, t is a time parameter, and θ₀ is determined according to a state of the circuit of the non-linear oscillator 100 when t=0. In this embodiment, the reference signal r is a DC voltage signal.

As shown in FIG. 1, the non-linear oscillator 100 includes a comparing device 2, a computing device 7 coupled to the comparing device 2, an integrator device 6 coupled to the computing device 7, and a feedback device 1 coupled to the comparing device 2, the computing device 7 and the integrator device 6. The computing device 7 includes a first signal generator 3, a second signal generator 4, and a combining module 5.

Regarding the first sinusoidal signal x₁(t), the comparing device 2 is configured for receiving the DC voltage signal r, and is operable to compare the DC voltage signal r with a feedback signal from the feedback device 1 and output a comparison signal based on result of comparison made thereby. The first signal generator 3 is configured to compute a first intermediate signal based upon the comparison signal, the feedback signal, and the first sinusoidal signal x₁(t) from the integrator device 6, and the second signal generator 4 is configured to generate a third intermediate signal according to the second sinusoidal signal x₂(t) from the integrator device 6. Then, the combining module 5 is configured to combine the first and third intermediate signals to generate a first combined signal, and the integrator device 6 is operable to perform integration upon the first combined signal to output the first sinusoidal signal x₁(t). The feedback device 1 is operable to output the feedback signal to the comparing device 2 and the first signal generator 3 according to the first and second sinusoidal signals x₁(t), x₂(t) from the integrator device 6.

Similarly, regarding the second sinusoidal signal x₂(t), the first signal generator 3 is further configured to compute a second intermediate signal based upon the comparison signal, the feedback signal and the second sinusoidal signal x₂(t), and the second signal generator 4 is further configured to generate a fourth intermediate signal according to the first sinusoidal signal x₁(t). Then, the combining module 5 is configured to combine the second and fourth intermediate signals to generate a second combined signal, and the integrator device 6 is operable to perform integration upon the second combined signal to output the second sinusoidal signal x₂(t).

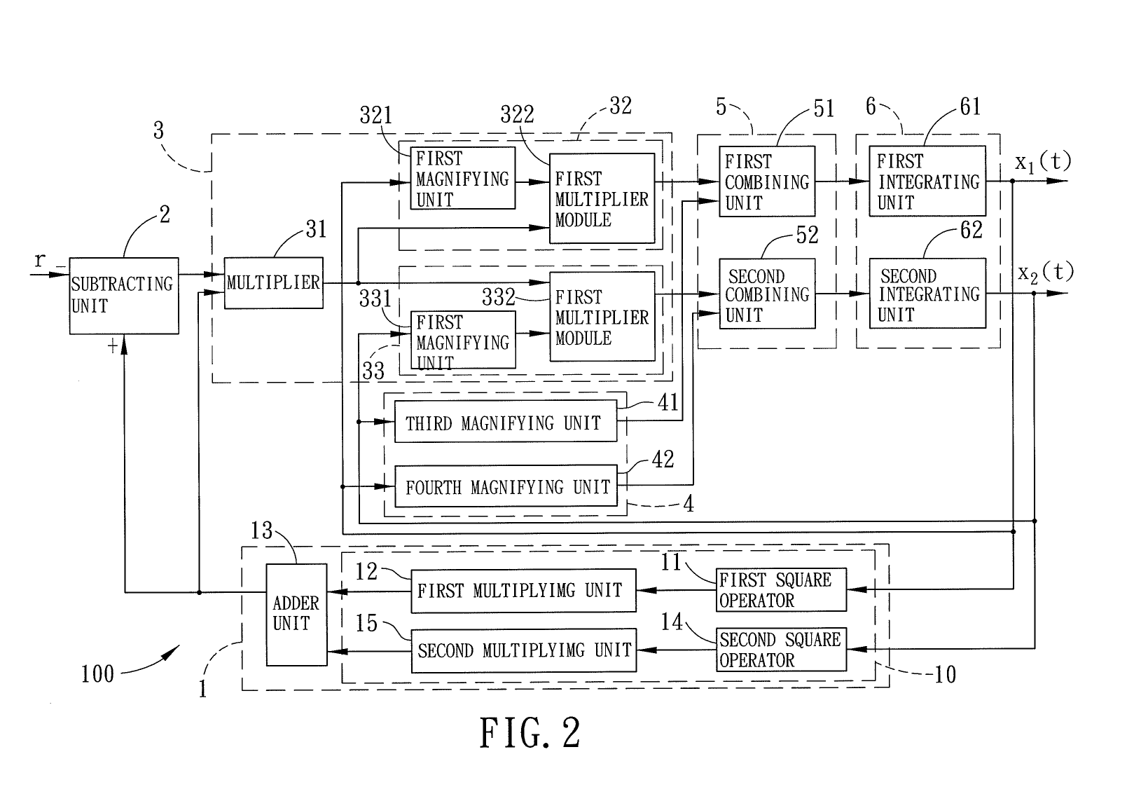

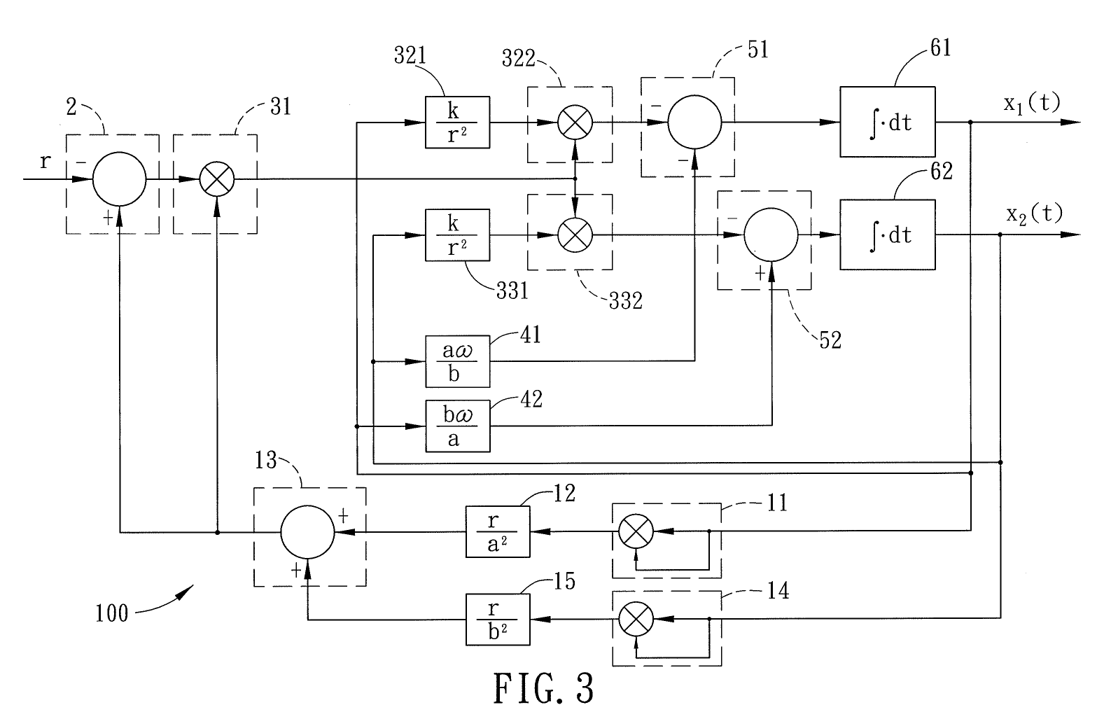

Referring to FIGS. 2 and 3, the comparing device is configured as a subtracting unit to obtain a difference between the DC voltage signal r and the feedback signal to result in the comparison signal.

The first signal generator 3 includes a multiplier 31, a first computing module 32 and a second computing module 33. The multiplier 31 is coupled to the comparing device 2, and is configured to compute a product of the comparison signal and the feedback signal and output the product to the first and second computing modules 32, 33. The first computing module 32 includes a first magnifying unit 321 coupled to the integrator device 6, and a first multiplier module 322 coupled to the first magnifying unit 321 and the multiplier 31. The first magnifying unit 321 is operable to magnify the first sinusoidal signal x₁(t) by a particular multiple (W), where k is a positive number related to a convergence factor. Subsequently, the first multiplier module 322 is operable to multiply the product from the multiplier 31 by the magnified first sinusoidal signal from the first magnifying unit 321 so as to generate the first intermediate signal. Similarly, the second computing module 33 includes a second magnifying unit 331 coupled to the integrator device 6, and a second multiplier module 332 coupled to the second magnifying unit 331 and the multiplier 31. The second magnifying unit 331 is operable to magnify the second sinusoidal signal x₂(t) by the particular multiple (k/r²), and the second multiplier module 332 is operable to subsequently multiply the product from the multiplier 31 by the magnified second sinusoidal signal from the second magnifying unit 331 so as to generate the second intermediate signal.

The second signal generator 4 includes a third magnifying unit 41 and a fourth magnifying unit 42 that are coupled to the integrator device 6. The third magnifying unit 41 is operable to magnify the second sinusoidal signal x₂(t) by a multiple (aω/b) so as to generate the third intermediate signal, and the fourth magnifying unit 42 is operable to magnify the first sinusoidal signal x₁(t) by a multiple (bω/a) so as to generate the fourth intermediate signal. Therefore, the second signal generator 4 adjusts an amplitude of the second sinusoidal signal x₂(t) according to the predetermined amplitude values a, b and the predetermined frequency value ω to generate the third intermediate signal, and adjusts an amplitude of the first sinusoidal signal x₁(t) according to the predetermined amplitude values a, b and the predetermined frequency value ω to generate the fourth intermediate signal.

The combining module 5 includes a first combining unit 51 coupled to the first multiplier module 322 of the first computing module 32 and the third magnifying unit 41 of the second signal generator 4, and a second combining unit 52 coupled to the second multiplier module 332 of the second computing module 33 and the fourth magnifying unit 42 of the second signal generator 4. The first combining unit 51 is configured to combine a negative value of the first intermediate signal and a negative value of the third intermediate signal so as to generate the first combined signal. The second combining unit 52 is configured to subtract the second intermediate signal from the fourth intermediate signal so as to generate the second combined signal.

The integrator device 6 includes a first integrating unit 61 coupled to the first combining unit 51, and a second integrating unit 62 coupled to the second combining unit 52. The first integrating unit 61 is operable to perform integration upon the first combined signal from the first combining unit 51 with respect to time t so as to generate the first sinusoidal signal x₁(t). The second integrating unit 62 is operable to perform integration upon the second combined signal from the second combining unit 52 with respect to time t so as to generate the second sinusoidal signal x₂(t). Those skilled in the art may appreciate that resistors, capacitors and operational amplifiers may be used for realizing the first and second integrating units 61, 62.

The feedback device 1 includes a calculating circuit 10, and an adder unit 13 coupled to the calculating circuit 10. The calculating circuit 10 includes first and second square operators 11, 14 coupled respectively to the first and second integrating units 61, 62, and first and second multiplying units 12, 15 coupled respectively to the first and second square operators 11, 14. The first square operator 11 is configured to compute a square of the first sinusoidal signal x₁(t), and the first multiplying unit 12 is configured to multiply the square of the first sinusoidal signal x₁(t) by a multiple (r/a²) so as to generate a first calculation signal. The second square operator 14 is configured to compute a square of the second sinusoidal signal x₂(t), and the second multiplying unit 15 is configured to multiply the square of the second sinusoidal signal x₂(t) by a multiple (r/b²) so as to generate a second calculation signal. Then, the adder unit 13 is operable to combine the first and second calculation signals to result in the feedback signal.

In practice, the calculating circuit 10 is not limited to the disclosure of this embodiment, and other configurations capable of generating the first and second calculation signals may be readily appreciated by those skilled in the art. The first calculation signal is a product of the square of the first sinusoidal signal xₜ(t) and the multiple (r/a²), i.e., (rx₁²(t))/a², and the second calculation signal is a product of the square of the second sinusoidal signal x₂(t) and the multiple (r/b²), i.e., (rx₂²(t)/b².

Considering the operation of the components as shown in FIG. 2, dynamic equations of the non-linear oscillator 100 can be expressed as

$$\begin{matrix}{\dot{x}}_{1} ( t ) = - \frac{a ω}{b} {x}_{2} ( t ) - \frac{k}{{r}^{2}} {x}_{1} ( t ) \cdot [ \frac{{rx}_{1}^{2} ( t )}{{a}^{2}} + \frac{{rx}_{2}^{2} ( t )}{{b}^{2}} ] \cdot [ \frac{{rx}_{1}^{2} ( t )}{{a}^{2}} + \frac{{rx}_{2}^{2} ( t )}{{b}^{2}} - r ] \\ = - \frac{a ω}{b} {x}_{2} ( t ) - {kx}_{1} ( t ) \cdot [ \frac{{x}_{1}^{2} ( t )}{{a}^{2}} + \frac{{x}_{2}^{2} ( t )}{{b}^{2}} ] \cdot [ \frac{{x}_{1}^{2} ( t )}{{a}^{2}} + \frac{{x}_{2}^{2} ( t )}{{b}^{2}} - 1 ]\end{matrix} \\ \begin{matrix}{\dot{x}}_{2} ( t ) = - \frac{b ω}{a} {x}_{1} ( t ) - \frac{k}{{r}^{2}} {x}_{2} ( t ) \cdot [ \frac{{rx}_{1}^{2} ( t )}{{a}^{2}} + \frac{{rx}_{2}^{2} ( t )}{{b}^{2}} ] \cdot [ \frac{{rx}_{1}^{2} ( t )}{{a}^{2}} + \frac{{rx}_{2}^{2} ( t )}{{b}^{2}} - r ] \\ = - \frac{b ω}{a} {x}_{1} ( t ) - {kx}_{2} ( t ) \cdot [ \frac{{x}_{1}^{2} ( t )}{{a}^{2}} + \frac{{x}_{2}^{2} ( t )}{{b}^{2}} ] \cdot [ \frac{{x}_{1}^{2} ( t )}{{a}^{2}} + \frac{{x}_{2}^{2} ( t )}{{b}^{2}} - 1 ]\end{matrix} \qquad ( 1 )$$

where x₁(t) and x₂(t) are differential equations of x₁(t) and x₂(t) with respect to time t, and the DC voltage signal r has a voltage value equal to 1 in this embodiment.

According to the limit cycle and Bellman-Gronwall Inequality (with reference to Sun Y J., “The existence of the exponentially stable limit cycle for a class of nonlinear systems,” Chaos, Solitons & Fractals, Vol. 39, issue 5, pages 2357-2362, 15 Mar. 2009), it can be appreciated that the first and second sinusoidal signals x₁(t) and x₂(t) will converge as described in the following Equation (2) regardless of the value of

$$\frac{{x}_{1}^{2} ( 0 )}{{a}^{2}} + \frac{{x}_{2}^{2} ( 0 )}{{b}^{2}} - 1.$$

$$\vert {x}_{1} ( t ) - a cos ( ω t + {θ}_{0} ) \vert \leq m {e}^{- k α t} \\ \vert {x}_{2} ( t ) - b cos ( ω t + {θ}_{0} ) \vert \leq m {e}^{- k α t} \\ where \\ m = \{ \sqrt{\vert \frac{{x}_{1}^{2} ( 0 )}{{a}^{2}} + \frac{{x}_{2}^{2} ( 0 )}{{b}^{2}} - 1 \vert} \} \cdot max \{ \vert a \vert , \vert b \vert \} , \\ α = min \{ 1 , {[ \frac{{x}_{1}^{2} ( 0 )}{{a}^{2}} + \frac{{x}_{2}^{2} ( 0 )}{{b}^{2}} ]}^{2} \} , and \\ {θ}_{0} = {tan}^{- 1} ( \frac{{ax}_{2} ( 0 )}{{bx}_{1} ( 0 )} ) \qquad ( 2 )$$

In Equation (2), x₁(0) and x₂(0) respectively depend on initial voltage values of capacitors of the integrating units 61 and 62, and the phase θ₀ of the first and second sinusoidal signals x₁(t) and x₂(t) is determined based upon a product of the first predetermined amplitude value a and x₂(0) with respect to a product of the second predetermined amplitude value b and x₁(0).

From the foregoing, it can be concluded that once parameters of relevant components of the non-linear oscillator 100 have been set properly, the first and second sinusoidal signals x₁(t) and x₂(t) thus obtained can be expected to have amplitude values a and b and a frequency value ω. For instance, when the multiples used in the third and fourth magnifying units 41, 42 of the second signal generator 4 are respectively set as (aω/b), and (bω/a), and the multiples used in the first and second multiplying units 12, 15 of the feedback device 1 are respectively set as (r/a²) and (r/b²), the first and second sinusoidal signals x₁(t) and x₂(t) thus generated by the non-linear oscillator 100 will approximate a cos(ωt+θ₀) and b sin(ωt+θ₀), respectively.

Moreover, the multiples used in the first and second magnifying units 321, 331 can be set as (k/r²) for controlling a convergence speed of the first and second sinusoidal signals x₁(t) and x₂(t). Generally, the greater convergence factor k results in a faster convergence speed.

Further, although x₁(0) and x₂(0) are determined directly based upon the initial voltage values of the capacitors of the first and second integrating units 61 and 62, the initial voltage values will not affect continuous oscillatory properties of the first and second sinusoidal signals x₁(t) and x₂(t). The initial voltage values will affect at most the phase θ₀ of the first and second sinusoidal signals x₁(t) and x₂(t), and indirectly affect the convergence speed.

It should be noted that, although the voltage value of the DC voltage signal r is assumed to be 1 to facilitate description of the convergence of the first and second sinusoidal signals x₁(t) and x₂(t) in Equation (2), the first and second sinusoidal signals x₁(t) and x₂(t) will oscillate continuously and approximate the expected sinusoidal waves regardless of the voltage value of the DC voltage signal r in other embodiments.

In a simulation experiment, the parameters of the non-linear oscillator 100 are set as:

the first predetermined amplitude value a=5;

the second predetermined amplitude value b=4;

the predetermined frequency value ω=3; and

the convergence factor k=1.

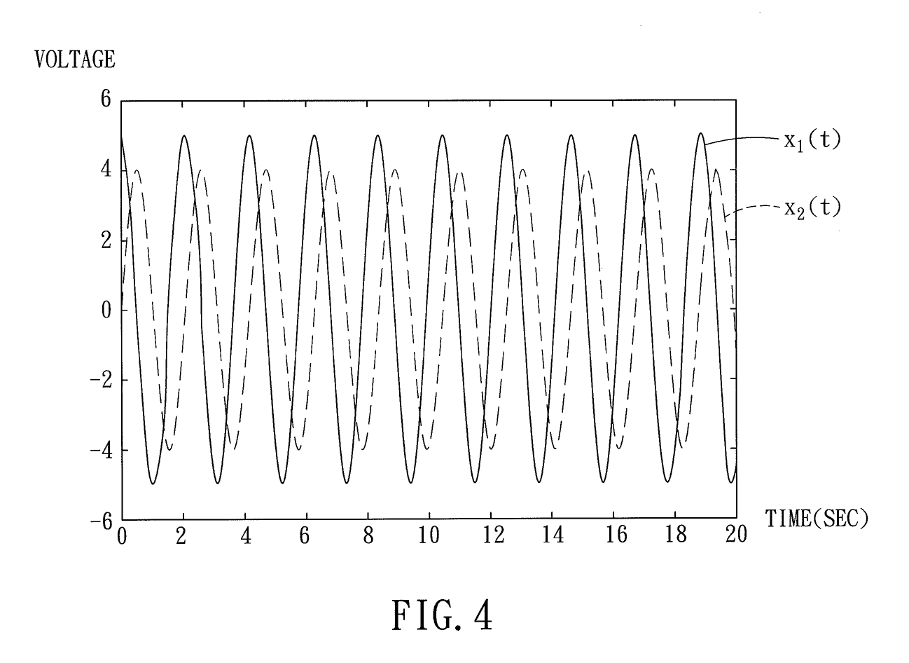

The voltage value of the DC voltage signal r=1 is substituted into the dynamic equations of the non-linear oscillator 100, Equation (1), and the dynamic equations are subsequently integrated to thereby obtain a simulation result as shown in FIG. 4. From FIG. 4, it can be appreciated that the first sinusoidal signal x₁(t) indicated by a solid line approximates 5 cos(3t+θ₀), and the second sinusoidal signal x₂(t) indicated by a dashed line approximates 4 sin(3t+θ₀).

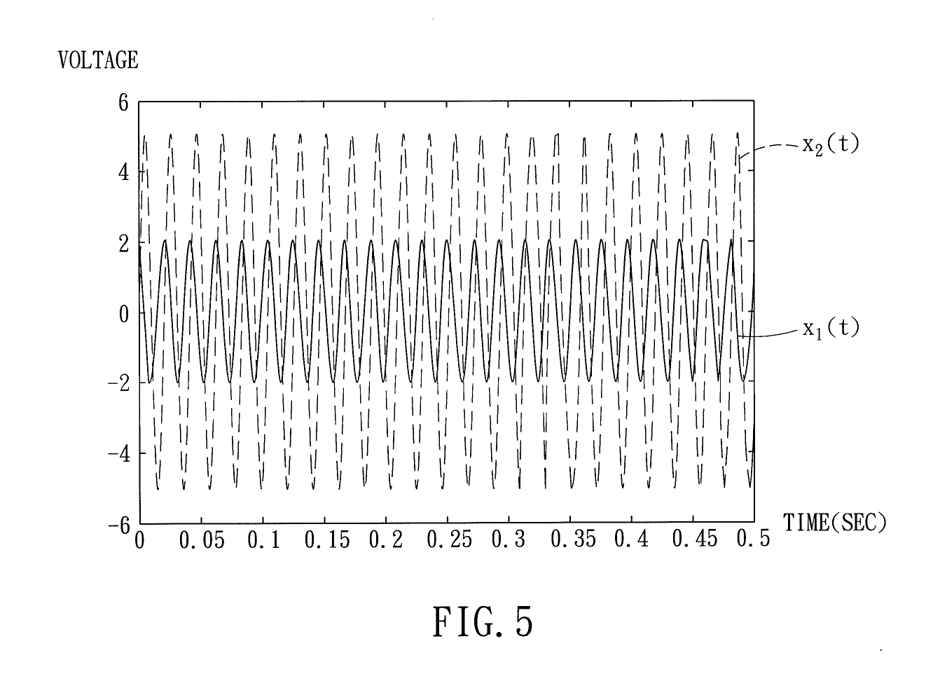

Further, when the non-linear oscillator 100 is setup using another set of parameters different from the above example, the waveforms of the first and second sinusoidal signals x₁(t), x₂(t) will be different. Taking FIG. 5 as an example, when a=2, b=5, (ω=300 and k=5, the first sinusoidal signal x₁(t) indicated by a solid line approximates 2 cos(300t+θ₀), and the second sinusoidal signal x₂(t) indicated by a dashed line approximates 5 sin(300t+θ₀).

It should be noted that, although the first and second predetermined amplitude values a and b are different from each other in the above simulation experiments, the first and second predetermined amplitude values a and b may be the same in practice.

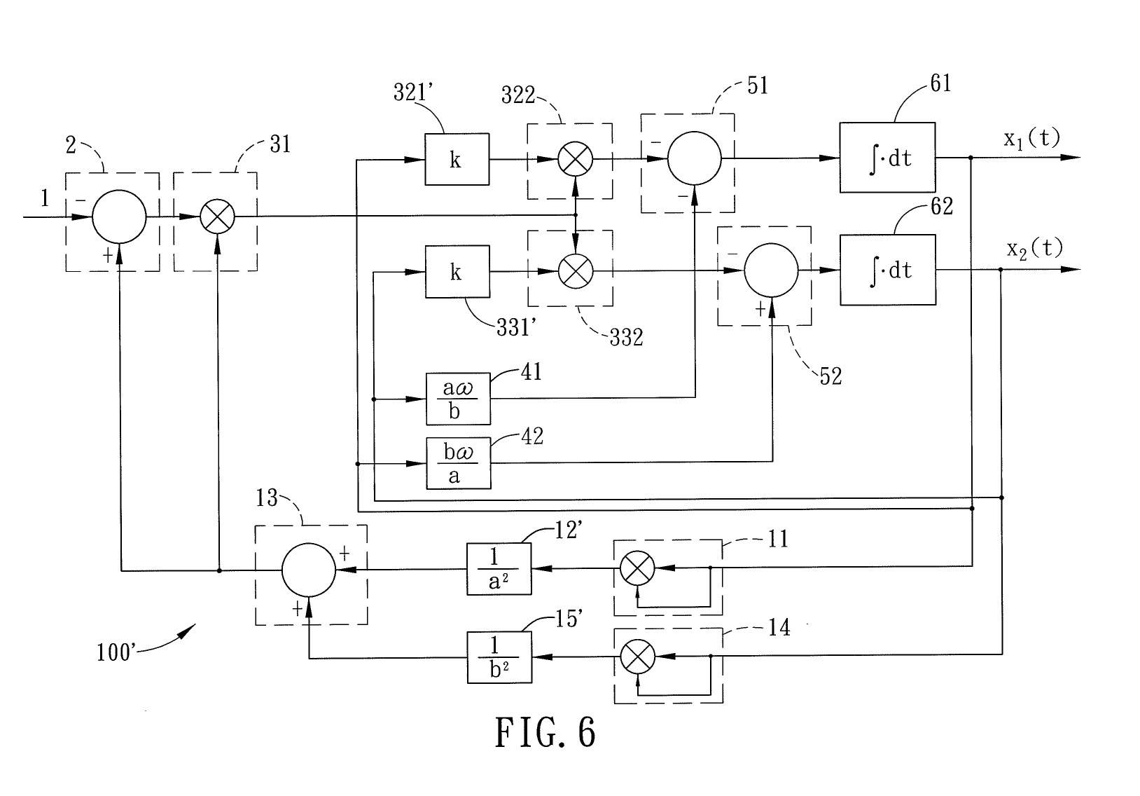

Referring to FIG. 6, a second preferred embodiment of a non-linear oscillator 100′ of the present invention is similar to the non-linear oscillator 100 of the first preferred embodiment. In this embodiment, the comparing device 2 is configured for receiving a reference signal having a value of 1. The first and second magnifying units 321′, 331′ are operable to magnify respectively the first and second sinusoidal signals x₁(t), x₂(t) by a particular multiple k, and the first and second multiplying units 12′, 15′ are configured to magnify the square of the first and second sinusoidal signals x₁(t) and x₂(t) by (1/a²) and (1/b²), respectively. Thus, the dynamic equations of the non-linear oscillator 100′ can be expressed as

$${\dot{x}}_{1} ( t ) = - \frac{a ω}{b} {x}_{2} ( t ) - {kx}_{1} ( t ) \cdot [ \frac{{x}_{1}^{2} ( t )}{{a}^{2}} + \frac{{x}_{2}^{2} ( t )}{{b}^{2}} ] \cdot [ \frac{{x}_{1}^{2} ( t )}{{a}^{2}} + \frac{{x}_{2}^{2} ( t )}{{b}^{2}} - 1 ] \\ {\dot{x}}_{2} ( t ) = - \frac{b ω}{a} {x}_{1} ( t ) - {kx}_{2} ( t ) \cdot [ \frac{{x}_{1}^{2} ( t )}{{a}^{2}} + \frac{{x}_{2}^{2} ( t )}{{b}^{2}} ] \cdot [ \frac{{x}_{1}^{2} ( t )}{{a}^{2}} + \frac{{x}_{2}^{2} ( t )}{{b}^{2}} - 1 ] \qquad ( 3 )$$

Accordingly, the first multiplying units 12′ outputs a first calculation signal as a square of the quotient of the first sinusoidal signal x₁(t) divided by the first predetermined amplitude value a, and the second multiplying units 15′ outputs a second calculation signal as a square of the quotient of the second sinusoidal signal x₂(t) divided by the second predetermined amplitude value b. In particular, the first multiplying unit 12′ is operable to multiply the square of the first sinusoidal signal Mt) from the first square operator 11 by (1/a²) so as to generate the first calculation signal, and the second multiplying unit 15′ is operable to multiply the square of the second sinusoidal signal x₂(t) from the second square operator 14 by (1/b²) so as to generate the second calculation signal.

In conclusion, the non-linear oscillator 100, 100′ according to the present invention is capable of generating the first and second sinusoidal signals Mt), x₂(t) using simple electronic components. Further, the non-linear oscillator 100, 100′ is less susceptible to being affected by environmental factors due to inherent non-linear properties thereof. Therefore, the non-linear oscillator 100, 100′ is capable of stably generating the sinusoidal signals, and manufacturing cost thereof is relatively less.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A non-linear oscillator for generating a first sinusoidal signal and a second sinusoidal signal, said non-linear oscillator being adapted to receive a reference signal and comprising:
a comparing device for receiving the reference signal and operable to compare the reference signal with a feedback signal and output a comparison signal based on result of comparison made thereby;
a computing device coupled to said comparing device and operable to output first and second combined signals according to a predetermined frequency value, the comparison signal, the feedback signal and the first and second sinusoidal signals;
an integrator device coupled to said computing device and operable to perform integration upon the first and second combined signals to output the first and second sinusoidal signals; and
a feedback device coupled to said comparing device, said computing device and said integrator device, and operable to output the feedback signal to said comparing device and said computing device according to a first predetermined amplitude value and the first and second sinusoidal signals from said integrator device.

2. The non-linear oscillator as claimed in claim 1, wherein said computing device includes:
a first signal generator including
a multiplier coupled to said comparing device and said feedback device, and configured to compute a product of the comparison signal and the feedback signal,
a first computing module configured to perform multiplication operation according to the product from said multiplier and the first sinusoidal signal from said integrator device so as to generate a first intermediate signal, and
a second computing module configured to perform multiplication operation according to the product from said multiplier and the second sinusoidal signal from said integrator device so as to generate a second intermediate signal;
a second signal generator configured to adjust an amplitude of the second sinusoidal signal according to the predetermined frequency value to generate a third intermediate signal, and to adjust an amplitude of the first sinusoidal signal according to the predetermined frequency value to generate a fourth intermediate signal; and
a combining module coupled to said first signal generator and said second signal generator, and configured to combine the first intermediate signal and the third intermediate signal to generate the first combined signal, and to combine the second intermediate signal and the fourth intermediate signal to generate the second combined signal.

3. The non-linear oscillator as claimed in claim 2, wherein said second signal generator is configured to adjust the amplitudes of the first and second sinusoidal signals according to the first predetermined amplitude value, a second predetermined amplitude value, and the predetermined frequency value so as to generate the third and fourth intermediate signals.

4. The non-linear oscillator as claimed in claim 3, wherein said second signal generator is configured to generate the third intermediate signal as the second sinusoidal signal multiplied by a product of the first predetermined amplitude value and the predetermined frequency value divided by the second predetermined amplitude value, and the fourth intermediate signal as the first sinusoidal signal multiplied by a product of the second predetermined amplitude value and the predetermined frequency value divided by the first predetermined amplitude value.

5. The non-linear oscillator as claimed in claim 2, wherein:
said first computing module is operable to magnify the first sinusoidal signal by a particular multiple, and to subsequently multiply the product from said multiplier by the magnified first sinusoidal signal so as to generate the first intermediate signal; and
said second computing module is operable to magnify the second sinusoidal signal by the particular multiple, and to subsequently multiply the product from said multiplier by the magnified second sinusoidal signal so as to generate the second intermediate signal.

6. The non-linear oscillator as claimed in claim 5, wherein the reference signal is a DC voltage signal, the particular multiple is a quotient of a positive number divided by a square of a voltage value of the DC voltage signal, and said feedback device includes:
a calculating circuit configured to generate a first calculation signal as a product of a square of the first sinusoidal signal and the voltage value divided by a square of the first predetermined amplitude value, and a second calculation signal as a product of a square of the second sinusoidal signal and the voltage value divided by a square of a second predetermined amplitude value; and
an adder unit coupled to said calculating circuit and configured to combine the first and second calculation signals to result in the feedback signal.

7. The non-linear oscillator as claimed in claim 6, wherein said calculating circuit includes:
a first square operator configured to compute the square of the first sinusoidal signal;
a second square operator configured to compute the square of the second sinusoidal signal;
a first multiplying unit coupled to said first square operator and configured to compute the product of the square of the first sinusoidal signal and the voltage value of the DC voltage signal divided by the square of the first predetermined amplitude value to obtain the first calculation signal; and
a second multiplying unit coupled to said second square operator and configured to compute the product of the square of the second sinusoidal signal and the voltage value of the DC voltage signal divided by the square of the second predetermined amplitude value to obtain the second calculation signal.

8. The non-linear oscillator as claimed in claim 5, wherein the reference signal has a value of 1, the particular multiple is a positive number, and said feedback device includes:
a calculating circuit configured to generate a first calculation signal as a product of a square of the first sinusoidal signal and a reciprocal of a square of the first predetermined amplitude value, and a second calculation signal as a product of a square of the second sinusoidal signal and a reciprocal of a square of a second predetermined amplitude value; and
an adder unit coupled to said calculating circuit and configured to combine the first and second calculation signals to result in the feedback signal.

9. The non-linear oscillator as claimed in claim 8, wherein said calculating circuit includes:
a first square operator configured to compute the square of the first sinusoidal signal;
a second square operator configured to compute the square of the second sinusoidal signal;
a first multiplying unit coupled to said first square operator and configured to compute the product of the square of the first sinusoidal signal and the reciprocal of the square of the first predetermined amplitude value to obtain the first calculation signal; and
a second multiplying unit coupled to said second square operator and configured to compute the product of the square of the second sinusoidal signal and the reciprocal of the square of the second predetermined amplitude value to obtain the second calculation signal.

10. The non-linear oscillator as claimed in claim 1, wherein said comparing device is configured to obtain a difference between the reference signal and the feedback signal to result in the comparison signal.
